(19) United States
(12) Patent Application Publication
(10) Pub. No.: US 2005/0275006 A1
(43) Pub. Date: Dec. 15, 2005

(54) [MULTI-GATE DRAM WITH DEEP-TRENCH CAPACITOR AND FABRICATION THEREOF]

(76) Inventor: Ming Tang, Hualien County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,719

(22) Filed: May 25, 2004

(51) Int. Cl. H01L 27/108; H01L 21/20; H01L 31/119; H01L 29/76; H01L 29/94

(52) U.S. Cl. 257/301

(57) ABSTRACT

A multi-gate DRAM cell is described, including a multi-gate transistor and a deep trench capacitor. The transistor includes a semiconductor pillar, a multi-gate, a gate dielectric layer, a first and a second source/drain regions. The pillar is beside the deep trench capacitor not overlapping with the latter. The multi-gate is at least on three sidewalls of the pillar separated by the gate dielectric layer, and can be a treble gate or a surrounding gate. The first source/drain region is in the top portion of the pillar, and the second source/drain region in the pillar coupling with the deep trench capacitor.

### BACKGROUND OF INVENTION

1. Field of the Invention

The present invention relates to a semiconductor device and fabrication thereof. More particularly, the present invention relates to a multi-gate DRAM (Dynamic Random Access Memory) cell with a deep-trench capacitor, a DRAM array based on the multi-gate DRAM cell, and a DRAM process for forming the same.

2. Description of the Related Art

In recent generations of semiconductor industry, DRAM devices are frequently fabricated with deep-trench (DT) capacitors having large capacitance for higher performance. FIG. 1 illustrates a conventional DRAM cell in a cross-sectional view. The conventional DRAM cell includes a substrate 100 having a deep trench 102 therein, a capacitor 110 in the deep trench 102, and a lateral transistor 120, wherein the capacitor includes an outer plate 104, a dielectric layer 106 and an inner electrode 108 in the deep trench 102. The source 122b of the transistor 120 is electrically connected with the inner electrode 108 via a buried strap 130 formed in the substrate 100, and the drain 122a is connected with a bit line contact 140 that is connected with a bit line (not shown).

As the linewidth of DRAM process is reduced for raising the integration degree, the short channel effect of a transistor 120 becomes serious. Though the short channel effect can be reduced by increasing the doping concentration in the substrate, the increased doping concentration adversely leads to more junction diode leakage from the source/drain 122b/a. Accordingly, there is a trade-off between the short channel effect and the junction diode leakage of the lateral transistor 120.

Another type of DRAM cell with a deep trench capacitor in the prior art is proposed by C. J. Radens, et al. (IEDM Tech. Dig., p. 349, 2000), which is illustrated in FIG. 2. The DRAM cell includes a vertical transistor, wherein the gate 210 is formed on the sidewall of the deep trench 202 in the substrate 200 defining a vertical channel, and the source 220 is also a buried strap electrically connecting with the inner electrode 230 of the capacitor. The gate 210 is connected with a word line 240, and the drain 250 is electrically connected to a bit-line contact 260. Though the channel length of such a transistor is not restricted by the feature size, some electrical properties of the transistor still depend on the cell dimension. Specifically, the off current and the retention time are still issues in the DRAM process.

### SUMMARY OF INVENTION

In view of the foregoing, this invention provides a DRAM cell including a multi-gate transistor and a deep-trench capacitor, wherein the multi-gate design allows the transistor to have better performance.

Another object of this invention is to provide a DRAM array that is based on the DRAM cell of this invention.

Still another object of this invention is to provide a DRAM process for fabricating the DRAM device of this invention.

The DRAM cell of this invention includes a deep trench capacitor and a vertical transistor. The vertical transistor includes a semiconductor pillar beside the deep trench capacitor not overlapping with the latter, a multi-gate at least on three sidewalls of the pillar, a gate dielectric layer between the multi-gate and the pillar, a first source/drain region in the top portion of the pillar, and a second source/drain region in a lower portion of the pillar apart from the first source/drain region. The second source/drain region is coupled with the deep trench capacitor, and may be a buried strap electrically connected with the inner electrode of the deep-trench capacitor.

In embodiments of this invention, the multi-gate can be a treble gate on three sidewalls of the pillar that may further cover a portion of the top surface of the pillar, or a surrounding gate that surrounds the sidewalls of the pillar. In addition, the multi-gate may be a part of a word line for controlling the transistor.

The DRAM array of this invention is based on the aforementioned DRAM cell of this invention. The DRAM array includes rows and columns of deep-trench capacitors, aforementioned vertical transistors of this invention, word lines and bit lines. Each transistor is disposed adjacent to at least one deep trench capacitor along the column direction. Each word line is coupled with the multi-gates of the transistors in one row, and each bit line is coupled with the first source/drain regions of the transistors in one column.

When the multi-gates in the DRAM array of this invention are treble gates, a pair of adjacent transistors in one column preferably share a pillar and a first source/drain region in the pillar. In such embodiments, two deep-trench capacitors corresponding to the pair of adjacent transistors are disposed at two opposite sides of the pillar along the column direction. On the other hand, when the multigates are surrounding gates, each transistor has its own pillar surrounded by its gate, while each pillar may be disposed on the same side of the corresponding deep-trench capacitor along the column direction.

The DRAM process of this invention includes the following step at least. A deep trench capacitor is formed in a semiconductor substrate. An active area is defined over the substrate to form a semiconductor pillar beside the deep trench capacitor and to form an isolation area. A buried strap is formed in the substrate coupling with the deep trench capacitor. Then, a gate dielectric layer is formed on the pillar, and a word line including a multi-gate is formed over the substrate, wherein the multi-gate is at least on three sidewalls of the pillar. A source/drain region is formed in the top portion of the pillar, and a bit line is formed electrically connecting with the source/drain region. The pillar, the buried strap, the gate dielectric layer, the multi-gate and the source/drain region together constitute a vertical transistor.

In the DRAM process of this invention, when the multigate is to be formed as a treble gate further covering a portion of the top surface of the pillar, the word line is preferably formed with a deposition-patterning method. In such cases, a bit-line contact is further formed to electrically connect the source/drain region to the bit line. When the multi-gate is to be formed as a treble gate merely on three sidewalls of the pillar or a surrounding gate, the word line is preferably formed with a damascene method. In such cases, the bit line can be formed directly contacting with the source/drain region.

Since the multi-gate of the DRAM cell of this invention is formed on the sidewalls of the pillar, the channel length is independent of the ground rule, and can be increased as required to lower the off current. Meanwhile, the cell size can be easily reduced. Moreover, since the multi-gate is formed on more than one sidewalls of the pillar, the effective channel width of the transistor is increased to provide larger driving current and better current switching capability.

Moreover, when the multi-gate is a surrounding gate, the pillar surrounded by the gate can be formed sufficiently thin for inducing full depletion therein in use of the DRAM device. In such cases, the current switching capability can be further improved, and the junction diode leakage can also be eliminated.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a conventional DRAM cell having a lateral transistor and a deep-trench capacitor in a cross-sectional view.

FIG. 2 illustrates another conventional DRAM cell with a deep-trench capacitor in a cross-sectional view.

FIGS. 3-5 respectively illustrate three embodiments of the DRAM cell of this invention in a perspective view, wherein the deep-trench capacitor is represented by the contact portion of its inner electrode for simplifying the figures.

FIGS. 6-8 respectively illustrate three embodiments of the DRAM array of this invention in a top view, wherein the DRAM array in FIG. 6/7/8 is based on the DRAM cell illustrated in FIG. 3/4/5.

FIGS. 9-17 illustrate a process flow of fabricating a DRAM device with deep-trench capacitors according to a first embodiment of this invention, wherein sub-figures (b) are illustrated in a simplified top view and sub-figures (a) in a cross-sectional view along line IX-IX′.

FIGS. 18-21 illustrate a process flow of fabricating a DRAM device with deep-trench capacitors according to a second embodiment of this invention, wherein sub-figures (b) are illustrated in a simplified top view and sub-figures (a) in a cross-sectional view along line IX-IX′. FIG. 18 follows FIG. 12 that is referred to in the description of the first embodiment.

FIGS. 22-27 illustrate a process flow of fabricating a DRAM device with deep-trench capacitors according to a third embodiment of this invention, wherein sub-figures (b) are illustrated in a simplified top view and sub-figures (a) in a cross-sectional view along line II-II′.

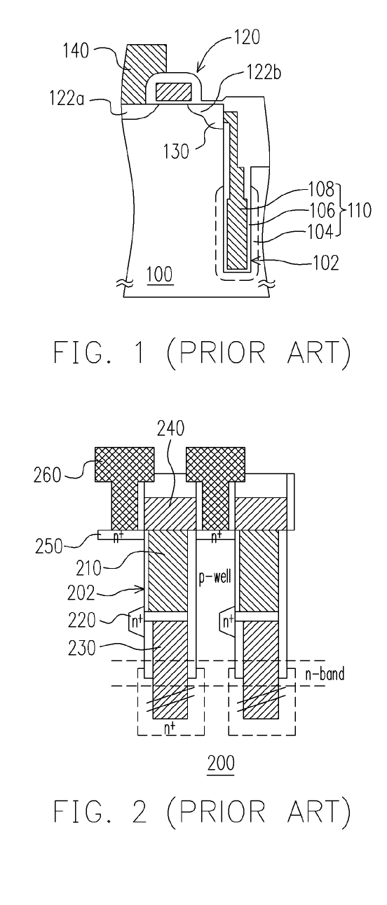

### DETAILED DESCRIPTION

Some embodiments of this invention are described below referring to the drawings, including embodiments of the DRAM cell, the DRAM array and the DRAM process according to this invention.

<DRAM Cell>

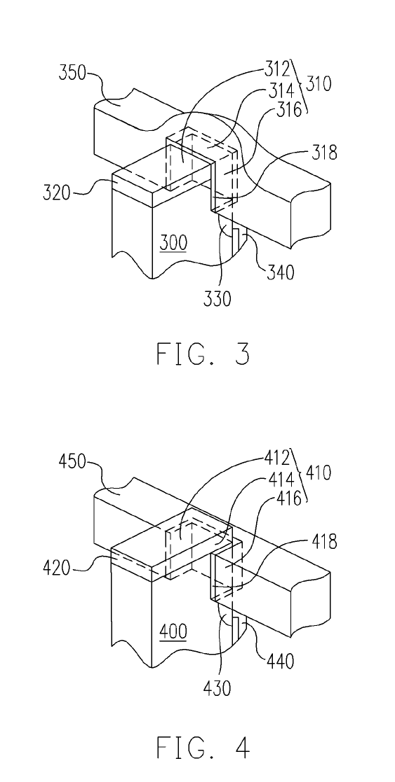

FIGS. 3-5 respectively illustrate three embodiments of the DRAM cell of this invention in a perspective view, wherein the deep-trench capacitor is represented by the contact portion (340, 440 or 540) of its inner electrode for simplifying the figures.

### First Embodiment

Referring to FIG. 3, the DRAM cell according to the first embodiment includes a deep-trench capacitor 340 and a transistor constituted of a semiconductor pillar 300, a multi-gate 310, a gate dielectric layer 318, a first source/drain region 320 and a second source/drain region 330. The semiconductor pillar 300 is disposed beside the deep-trench capacitor 340, and does not overlap with the deep-trench capacitor 340. The pillar 300 may be a single-crystal silicon pillar defined from a single-crystal silicon substrate, or a pillar made from other semiconductor material.

The multi-gate 310 may be a treble gate constituted of a first gate 312, a second gate 314 and a third gate 316 respectively on three sidewalls of the pillar 300, wherein the first sidewall faces the deep-trench capacitor 340 and the other two sidewalls are adjacent to the first sidewall. The multi-gate 310 may further cover a portion of the top surface of the pillar 300, and may be a part of a word line 350. The material of the multi-gate 310/word line 350 may be polycide, i.e., the multi-gate 310/word line 350 may include an N-doped polysilicon layer on the three sidewalls and the top of the pillar 300 and a metal silicide layer on the polysilicon layer. Alternatively, the multi-gate 310/word line 350 may include a metal layer, such as tungsten, replacing the metal silicide layer to reduce resistance.

Referring to FIG. 3 again, the gate dielectric layer 318 is formed between the pillar 300 and the treble gate 310. The material of the gate dielectric layer is, for example, silicon oxide that is formed with thermal oxidation or other suitable dielectrics with higher dielectric constant. The first source/drain region 320 is in the top portion of the pillar 300 for coupling with a bit line (not shown). The second source/drain 330 is located in a lower portion of the pillar 300 apart from the first source/drain region 320, and is coupled to the deep-trench capacitor 340. The second source/drain region 330 may be directly a buried strap electrically connecting with the contact portion 340 of the inner electrode of the deep-trench capacitor, as shown in the figure, and can be formed through out-diffusion of dopants from the contact portion 340.

### Second Embodiment

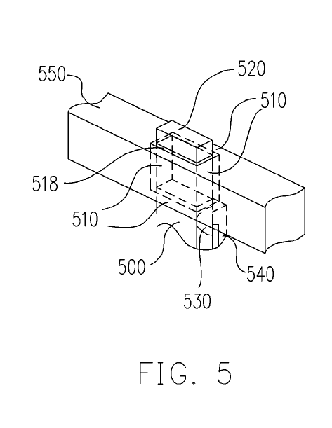

Referring to FIG. 4, the DRAM cell according to the second embodiment includes a deep-trench capacitor 440 and a transistor constituted of a semiconductor pillar 400, a multi-gate 410, a gate dielectric layer 418, a first source/drain region 420 and a second source/drain region 430. The semiconductor pillar 400 is disposed beside the deep-trench capacitor 440, and does not overlap with the deep-trench capacitor 440.

The multi-gate 410 may be a treble gate constituted of a first gate 412, a second gate 414 and a third gate 416 respectively on three sidewalls of the pillar 400, wherein the first sidewall faces the deep-trench capacitor 440 and the other two sidewalls are adjacent to the first sidewall. The multi-gate 410 is formed merely on the three sidewalls not covering a portion of the top surface of the pillar 400, and may be a part of a word line 450. Moreover, the top surface of the treble gate 410/word line 450 may be lower than that of the pillar 400, so that a bit line (not shown) can be formed directly contacting with the first source/drain region 420 after an insulting layer is formed on the word line 450 for insulating the word line 450 from the bit line formed latter. In addition, the material of the multigate 410/word line 450 includes, for example, N-doped polysilicon.

Referring to FIG. 4 again, the gate dielectric layer 418 is disposed between the pillar 400 and the treble gate 410. The first source/drain region 420 is in the top portion of the pillar 400 for coupling with a bit line (not shown), and may take the whole area of the top portion of the pillar 400. The second source/drain 430 is located in a lower portion of the pillar 400 apart from the first source/drain region 420, and is coupled to the deep-trench capacitor 440. The second source/drain region 430 may be directly a buried strap electrically connecting with the contact portion 440 of the inner electrode of the deep-trench capacitor, as shown in the figure, and can be formed through out-diffusion of dopants from the contact portion 440.

### Third Embodiment

Referring to FIG. 5, the DRAM cell according to the third embodiment includes a deep-trench capacitor 540 and a vertical transistor constituted of a semiconductor pillar 500, a multi-gate 510, a gate dielectric layer 518, a first source/drain region 520 and a second source/drain region 530. The semiconductor pillar 500 is disposed beside the deep-trench capacitor 540, and does not overlap with the deep-trench capacitor 540. The multi-gate 510 may be a surrounding gate surrounding the sidewalls of the pillar 500, and the pillar 500 can have a sufficiently small width, preferably smaller than the feature size, such as 200-600 Å, so that full depletion can be induced in the channel region in use of the DRAM device to significantly improving the performance of the device. The multi-gate 510 may be a part of a word line 550. Moreover, the top surface of the multi-gate 510/word line 550 may be lower than that of the pillar 500, so that a bit line (not shown) can be formed directly contacting with the first source/drain region 520 after an insulting layer is formed on the word line 550 for insulating the word line 550 from the bit line formed latter. In addition, the material of the surrounding gate 510/word line 550 includes, for example, N-doped polysilicon.

Referring to FIG. 5 again, the gate dielectric layer 518 is disposed between the pillar 500 and the surrounding gate 510. The first source/drain region 520 is in the top portion of the pillar 400 for coupling with a bit line (not shown), and takes the whole area of the top portion of the pillar 400. The second source/drain 530 is located in a lower portion of the pillar 500 apart from the first source/drain region 520, and is coupled to the deep-trench capacitor 540. The second source/drain region 530 may be directly a buried strap electrically connecting with the contact portion 540 of the inner electrode of the deep-trench capacitor, as shown in the figure, and can be formed through out-diffusion of dopants from the contact portion 540.

Since the multi-gate of the DRAM cell according to the first, second or third embodiment of this invention is formed on the sidewalls of the pillar, the channel length is independent of the ground rule, and can be increased as required to lower the off current. Meanwhile, the cell size can be easily reduced. Moreover, since the multi-gate is formed on more than one sidewalls of the pillar, the effective channel width is increased to provide larger driving current and better current switching capability.

Moreover, when the multi-gate is a surrounding gate as in the third embodiment of this invention, the pillar surrounded by the gate can be formed with a sufficiently small width for inducing full depletion therein in use of the DRAM device. In such cases, the current switching capability can be further improved, and the junction diode leakage can also be eliminated.

<DRAM Array>

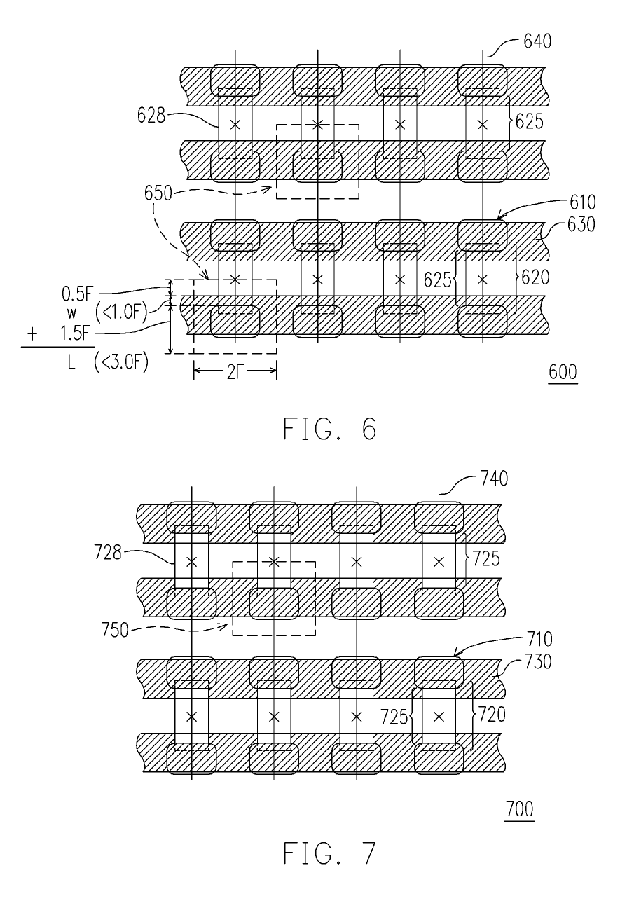

FIGS. 6-8 respectively illustrate three embodiments of the DRAM array of this invention in a top view, wherein the DRAM array in FIG. 6/7/8 is based on the DRAM cell illustrated in FIG. 3/4/5.

### First Embodiment

Referring to FIG. 6, the DRAM array according to the first embodiment is formed on a semiconductor substrate 600, including rows and columns of deep-trench capacitors 610 formed in the substrate 600. The active area mask 620 of each transistor 650 is defined overlapping with the corresponding deep-trench capacitor 610, so that a semiconductor pillar 625 as an active area is formed smaller than the active area mask 620. Each pillar 625 has a source/drain region 628 therein.

To reduce the area of each memory cell, it is preferable to have a pair of adjacent transistors 650 in one column share a pillar 625 and a source/drain region 628 in the pillar 625. In such a case, the two deep-trench capacitors 610 corresponding to the pair of transistors 650 are located on two opposite sides of the pillar 625 along the column direction. Each word line 630 is disposed along edge portions of the pillars 625 in one row covering a portion of the top surface of each pillar 625, so that a treble gate as mentioned above is formed on three sidewalls and the top of each pillar 625. Each bit line 640 is electrically connected to the source/drain regions 628 in the pillars 625 in one column.

Moreover, as shown in FIG. 6, the minimal width of a unit cell 650 is 2F, wherein F is the feature size. The minimal length of a unit cell is the sum of one half of the trench-to-trench distance (0.5F), the length of a trench (1.0F), the width “w” of the gate-pillar overlap (w<1.0F) and one half of the length of a source/drain region 628 shared by two cells (0.5F). Therefore, the minimal length of a unit cell is less than 3.0F, and DRAM array is a sub-6F² memory array to the limit of the lithographic resolution.

### Second Embodiment

Referring to FIG. 7, the DRAM array according to the second embodiment is similar to that according to the first embodiment (FIG. 6). That is, the arrangement of the deep-trench capacitors 710 in the substrate 700, the active area masks 720, the pillars 725 as active areas, the source/drain regions 728, the word lines 730 and the bit lines 740 are similar to that in the first embodiment. However, each word line 730 disposed along edge portions of the pillars 725 in one row does not cover a portion of the top surface of each pillar 725 in the row in this embodiment. Therefore, a treble gate is formed merely on three sidewalls of each pillar 725, as shown in FIG. 4. In addition, by comparing FIG. 6 and FIG. 7, it is clear that the DRAM array according to this embodiment can also be a sub-6F² memory array to the limit of the lithographic resolution.

### Third Embodiment

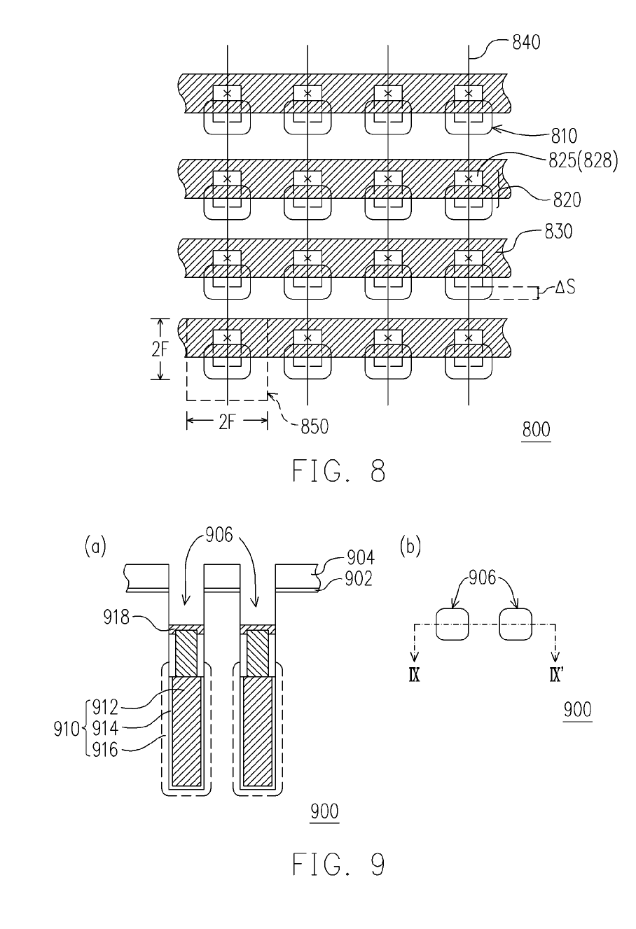

Referring to FIG. 8, the DRAM array according to the third embodiment is formed on a semiconductor substrate 800, including rows and columns of deep-trench capacitors 810 formed in the substrate 800. Each semiconductor pillar 825, with a width smaller than the feature size, as an active area is formed by overlapping the corresponding active area mask 820 with the corresponding deep-trench capacitor 810. Each pillar 825 is disposed adjacent to only one deep-trench capacitor 810, and has a source/drain region 828 therein.

To reduce the area of each memory cell, it is preferable to have each pillar 825 be disposed on the same side of the corresponding deep-trench capacitor 810 along the column direction. Each word line 830 is disposed surrounding each of the pillars 825 in one row, so that a surrounding gate as shown in FIG. 5 is formed surrounding each pillar 825. Each bit line 840 is electrically connected to the source/drain regions 828 in the pillars 825 in one column.

Particularly, the active area 825 of each transistor 850 may be defined by much overlapping the active area mask 820 with the corresponding deep-trench capacitor 810 with a small shift “AS” relative to the capacitor 810, so that the pillar 825 can be formed sufficiently thin to induce full depletion therein in use of the DRAM device. The width of each pillar 825 may be reduced to 200-600 Å for inducing full depletion effect. Moreover, as shown in FIG. 8, the minimal length and the minimal width of each unit cell 850 both can be 2.0F, so that the DRAM array can be a 4F² memory array to the limit of the lithographic resolution.

<DRAM Process>

### First Embodiment

FIGS. 9-17 illustrate a process flow of fabricating a DRAM device with deep-trench capacitors according to the first embodiment of this invention, wherein sub-figures (b) are illustrated in a simplified top view and sub-figures (a) in a cross-sectional view along line IX-IX′.

Referring to FIG. 9(a)/(b), multiple trenches 906 are formed in a semiconductor substrate 900 using a mask layer 904 as a mask, wherein the mask layer 904 may be a nitride layer formed on a pad oxide layer 902. A capacitor 910 including an inner electrode 912, a dielectric layer 914 and an outer plate 916 is then formed in each trench 906, wherein the inner electrode 912 is connected with a contact portion 918 for coupling with the transistor formed latter. The method for fabricating the deep-trench capacitors 910 in the trenches 906 can be any one well known in the art, such as, the method disclosed in U.S. Pat. No. 5,360,758 to Bronner et al. The inner electrode 912 and the contact portion 918 both can be made from N-doped polysilicon, and the outer electrode 916 is a doped region in the substrate 900 around the lower portion of the trench 906.

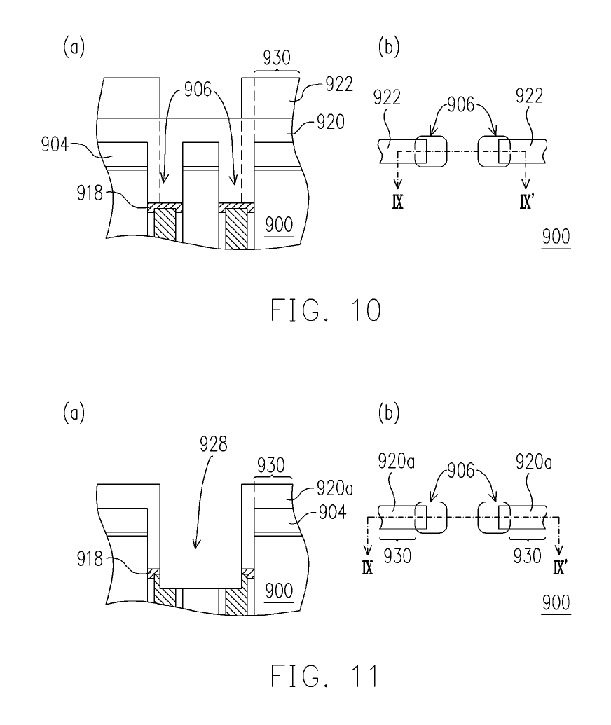

Referring to FIG. 10(a)/(b), a sacrificial layer 920, such as, an organic anti-reflective coating layer or a dielectric layer like silicon oxide or doped silicon oxide, is formed over the substrate 900 filling up the trenches 906. A patterned photoresist layer 922 for defining active areas 930 is then formed on the sacrificial layer 920, wherein each photoresist pattern 922 overlaps with the corresponding trench 906. The sacrificial layer 920 and the substrate 900 are then patterned using the patterned photoresist layer 922 as a mask, as indicated by the dashed lines.

Alternatively referring to FIG. 11(a)/(b), in case the sacrificial layer 920 is a dielectric layer, the sacrificial layer 920 may be firstly patterned as a hard mask layer 920a using the patterned photoresist layer 922 as a mask layer, and then the substrate 900 is patterned using the hard mask layer 920a as a mask layer to form a trench 928 of the STI structure formed latter as well as semiconductor pillars 930 that are separated by the trench 928. Since the photoresist pattern 922 overlaps with the adjacent deep trench 906, the corresponding pillar 930 as an active area is smaller than the photoresist pattern 922. A portion of each contact portion 918 is also removed in this step.

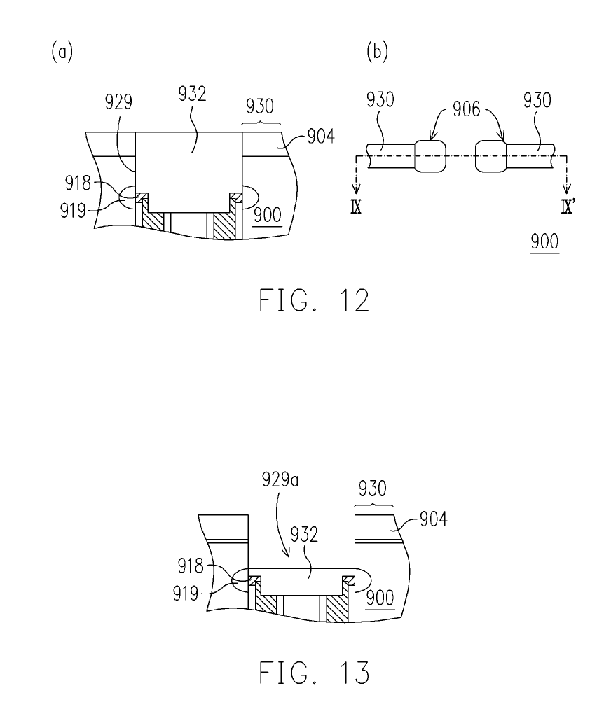

Referring to FIG. 12(a)/(b), the sacrificial layer 920 is removed to form a trench 929, and then an insulating material like silicon oxide is filled into the trench 929 and planarized to form a shallow trench isolation (STI) layer 932. Alternatively, when the hard mask layer 920a is also composed of another suitable insulating material, the insulating material can be directly filled into the trench 928 (FIG. 11) defined by the hard mask layer 920a. Then, the hard mask layer 920a and the insulating material outside the trench 929 are removed. Meanwhile, during the thermal process for forming the STI layer 932, the dopants in the contact portion 918 of the deep trench capacitor out-diffuse into the substrate 900 around the trench 906 to form a buried strap 919.

Referring to FIG. 13(a)/(b), the STI layer 932 is then recessed to a predetermined depth approximately the same level as the buried strap 919 to expose sidewalls of each pillar 930 and form a trench 929a.

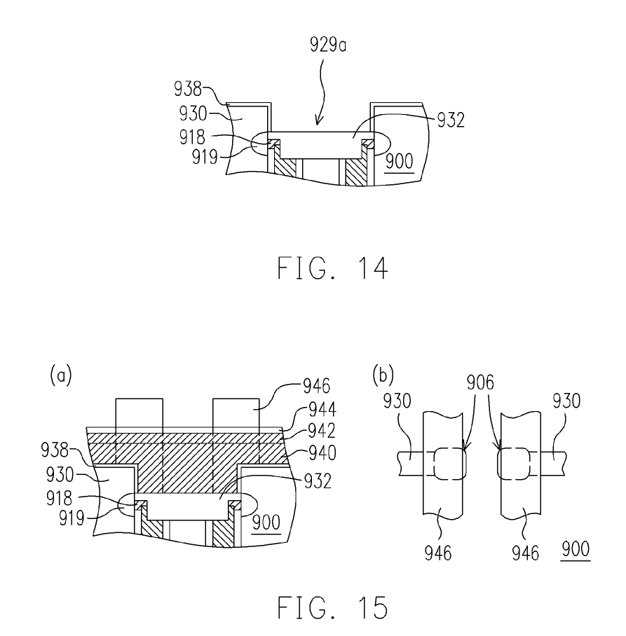

Referring to FIG. 14, the mask layer 904 and the pad oxide layer 902 are removed. Then, a gate dielectric layer 938 is formed on the exposed portion of each pillar 930 with, for example, thermal oxidation.

Referring to FIG. 15(a)/(b), a doped polysilicon layer 940 filling up the trench 929a, a metal comprising layer 942 (metal silicide or metal) and a capping layer 944 are sequentially formed over the substrate 900, wherein the capping layer 944 may be composed of SiN or SiON. A patterned mask layer 946 for defining word lines is then formed on the capping layer 944. A portion of the doped polysilicon layer 940 is on three sidewalls and a part of the top surface of a pillar 930, while a mask pattern 946 for defining the corresponding word line runs over the portion of the doped polysilicon layer 940.

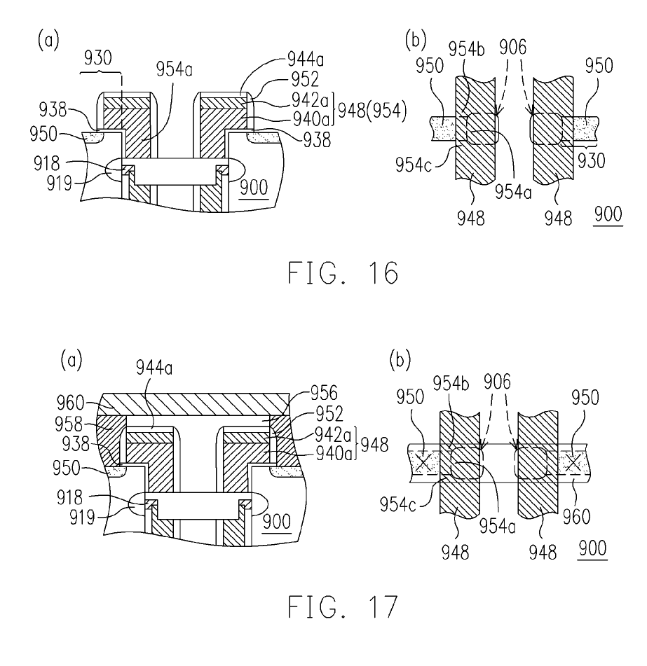

Referring to FIGS. 15 and 16, the capping layer 944, the metal comprising layer 942 and the doped polysilicon layer 940 are sequentially patterned using the mask layer 946 as a mask, wherein the patterned metal comprising layer 942a and the patterned doped polysilicon layer 940a together constitute word lines 948. According to the patterns of the mask layer 946 described above, each word line 948 includes a portion of the polysilicon layer 940a on three sidewalls and a part of the top surface of the corresponding pillar 930. Thereby, a treble gate 954 is formed including a first gate 954a on a first sidewall of the pillar 930 facing the trench 906 and a second gate 954b and a third gate 954c on the other two sidewalls adjacent to the first sidewall.

Thereafter, spacers 952, which may be composed of SiN or SiON, are formed on the sidewalls of the capping layers 944a and the word lines 948, and a source/drain region 950 is formed in the top portion of each pillar 930 using the corresponding word line 948 as a mask. A buried strap 919, a pillar 930, a gate dielectric layer 938, a treble gate 954 and a source/drain region 950 together constitute a multi-gate transistor.

Referring to FIG. 17, an insulating layer 956, such as, a silicon oxide layer, is formed over the substrate 900 covering the word lines 948. Bit-line contacts 958 are then formed through the insulating layer 956 contacting with the source/drain regions 950, and a bit line 960 is formed on the insulating layer 956 contacting with the bit-line contacts 958. Since each word line 948 is protected by the capping layer 944a thereon and the spacers 952 on the sidewalls thereof, the bit-line contacts 958 can be formed as self-aligned contacts (SAC).

### Second Embodiment

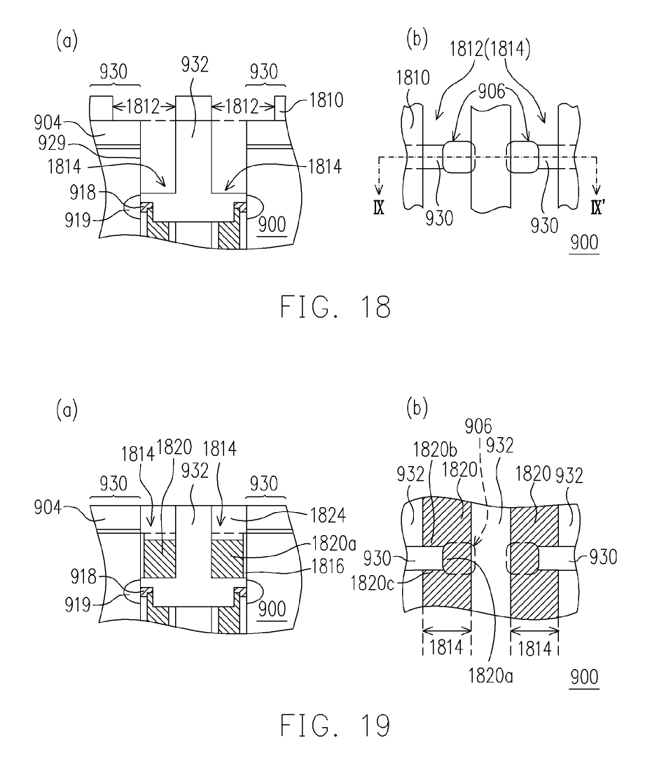

FIGS. 18-21 illustrate a process flow of fabricating a DRAM device with deep-trench capacitors according to the second embodiment of this invention, wherein sub-figures (b) are illustrated in a simplified top view and sub-figures (a) in a cross-sectional view along line IX-IX′. In addition, FIG. 18 follows FIG. 12 that is referred to in the description of the first embodiment.

Referring to FIG. 18, a patterned mask layer 1810 is formed over the substrate 900, over which a STI layer 932 has been formed. The mask layer 1810 has parallel trenches 1812 therein, wherein each trench 1812 exposes a portion of the corresponding pillar 930 and defines the location of a word line formed latter. Thereafter, the STI layer 932 is patterned using the mask layer 1810 as a mask to form trenches 1814 in the STI layer 932. Each trench 1814 exposes the first sidewall of the corresponding pillar 930 facing a deep trench 906 above a predetermined level and a portion of the second and third sidewalls of the same pillar 930 adjacent to the first sidewall above the predetermined depth approximately the same level as the buried strap 919.

Referring to FIG. 19, the mask layer 1810 is removed, and a gate oxide layer 1816 is formed on exposed portions of each pillar 930. Then, word lines 1820 are formed in the trenches 1814, wherein the top surface of each word line 1820 is lower than that of the substrate 900. The word lines 1820 may be formed by depositing a conductive material, such as, N-doped polysilicon, over the substrate 900 to fill up the trenches 1814 and then etching back the conductive material to the predetermined level.

Since a portion of three sidewalls of each pillar 930 is exposed by the corresponding trench 1814, the word line 1820 filled into the trench 1814 forms a treble gate. The treble gate includes a first gate 1820a on a first sidewall of the pillar 930 facing the trench 906 and a second gate 1820b and a third gate 1820c on the two sidewalls adjacent to the first sidewall. Thereafter, an insulating material 1824 is filled into the trenches 1814.

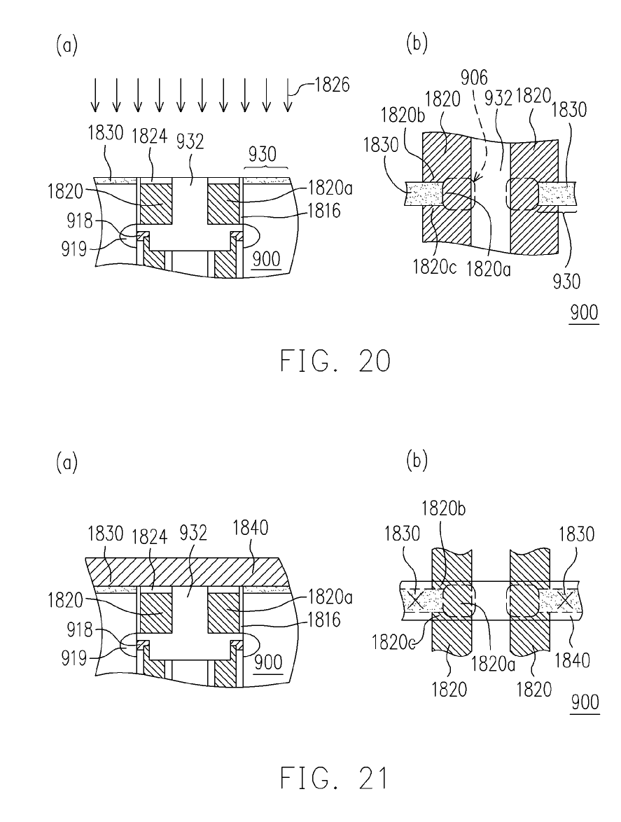

Referring to FIG. 20, the nitride mask layer 904 and the pad oxide layer 902 are removed, and the insulating material 1824 and the STI layer 932 higher than the top of the substrate 900 are also removed. Ion implantation 1826 is then performed to form a source/drain region 1830 in the whole top portion of each pillar 930, thereby forming a multi-gate transistor constituted of a buried strap 919, a pillar 930, a gate dielectric layer 1816, a treble gate 1820a/b/c and a source/drain region 1830.

Referring to FIG. 21, a bit line 1840 is then formed over the substrate 900 directly contacting with the source/drain regions 1830 in the same row, while the insulating material 1824 serves to insulate the bit line 1840 from the word lines 1820.

### Third Embodiment

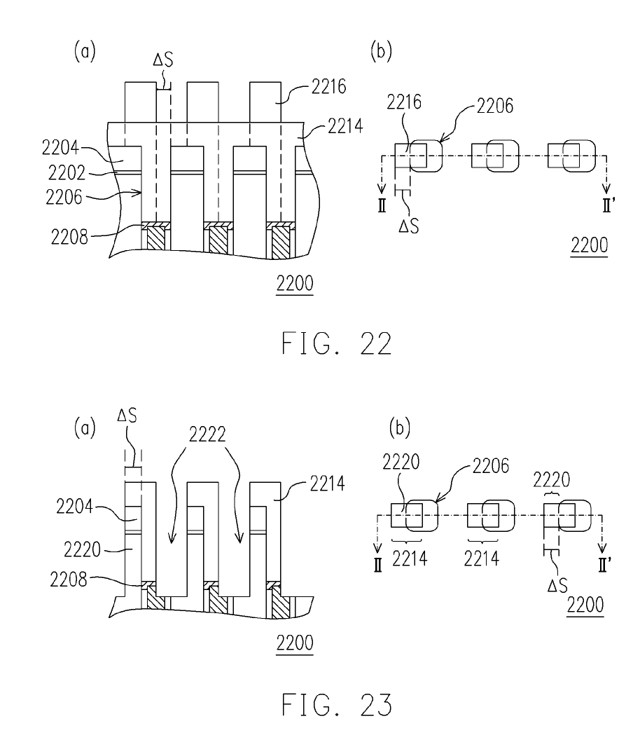

FIGS. 22-27 illustrate a process flow of fabricating a DRAM device with deep-trench capacitors according to the third embodiment of this invention, wherein sub-figures (b) are illustrated in a simplified top view and sub-figures (a) in a cross-sectional view along line II-II′.

Referring to FIG. 22, a semiconductor substrate 2200 is provided, and deep trenches 2206 are formed therein using a patterned mask layer 2204 as a mask, wherein the mask layer may be a nitride layer on a pad oxide layer 2202. A deep trench capacitor, which is represented by its contact portion 2208 in the figure, is formed in each deep trench 2206. Then, a sacrificial layer 2214, such as, a silicon oxide layer, is formed over the substrate 2200 filling up the deep trenches 2206. A patterned photoresist layer 2216 for defining active areas is then formed on the sacrificial layer 2214. Each photoresist pattern 2216 for defining an active area corresponds to one deep trench 2206 and much overlaps with the deep trench 2206 with a position shift “ΔS” from the deep trench 2206.

Referring to FIG. 23, the sacrificial layer 2214 is patterned using the patterned photoresist layer 2216 (FIG. 22) as a mask layer, and then the substrate 2200 is patterned using the sacrificial layer 2214 as a mask layer to form trenches 2222 and pillars 2220. Since a photoresist pattern 2216 much overlaps with the corresponding deep trench 2206, the pillar 2220 is quite thin and has a width relative to AS. The width of the pillar 2220 is preferably smaller than the feature size, and more preferably sufficiently small, approximately in the range of 200-600 Å, for inducing full depletion in the pillar 2220 in use of the DRAM device.

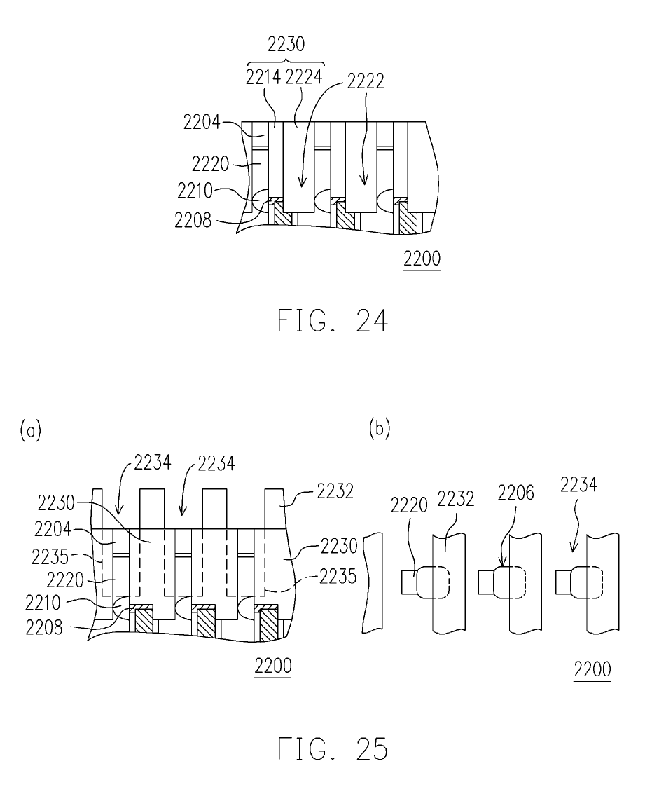

Referring to FIG. 24, when the sacrificial layer 2214 is composed of a suitable insulating material, such as silicon oxide, an insulating material 2224 can be filled into the trenches 2222 to constitute a STI layer 2230 together with the sacrificial layer 2214, and then the sacrificial layer 2214 and the insulating material 2224 higher than the mask layer 2204 are removed. Alternatively, the STI layer 2230 can be formed by removing the sacrificial layer 2214 and then filling the resulting trenches with an insulating material. Meanwhile, a buried strap 2210 is formed in the substrate 2200 around each contact portion 2208 through out-diffusion of dopants from the contact portion 2208.

Referring to FIG. 25, a patterned mask layer 2232 is formed over the substrate 2200, having linear trenches 2234 therein defining the locations of linear trenches 2235 in the STI layer 2230 for forming word lines. In the structure, the whole area of each pillar 2220 is completely within the boundary of one trench 2234.

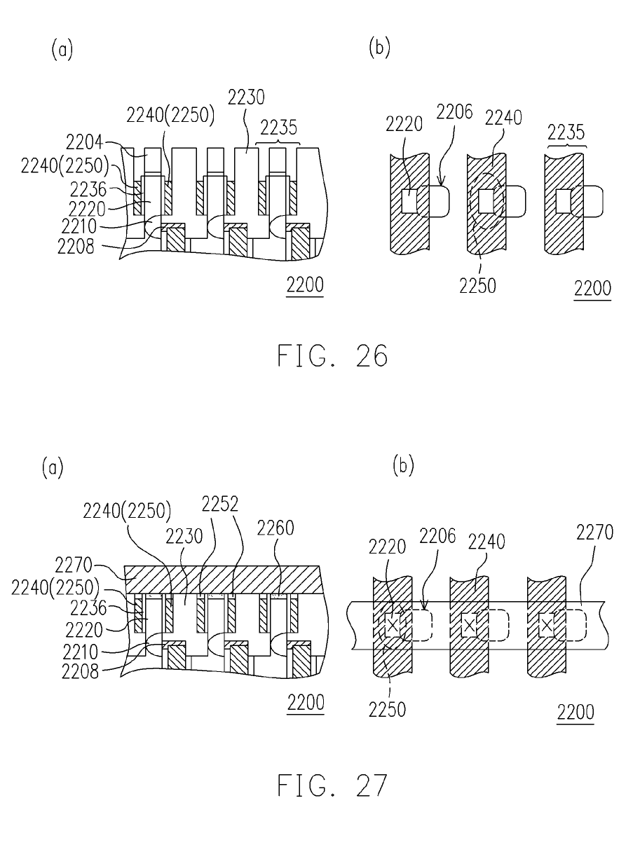

Referring to FIG. 26, linear trenches 2235 defining the locations of word lines are formed in the STI layer 2230 using the mask layer 2232 (FIG. 25) as a mask, so that all sidewalls of each pillar 2220 are exposed. After the mask layer 2232 is removed, a gate dielectric layer 2236 is formed on the exposed portions, i.e., all sidewalls, of each pillar 2220, thereby surrounding the pillar 2220. Word lines 2240 are then formed in the trenches 2235, wherein the top surface of each word line 2240 is lower than that of each pillar 2220. The word lines 2240 may be formed by depositing a conductive material over the substrate 2200 to fill up the trenches 2235 and then etching back the conductive material to the predetermined level. Since all sidewalls of a pillar 2220 are exposed in a trench 2235, the corresponding word line 2240 completely surrounds the pillar 2220 to form a surrounding gate 2250 that is separated from the pillar 2220 by the gate dielectric layer 2236.

Referring to FIG. 27, an insulating layer 2252 is formed to fill up the trenches 2235. The mask layer 2204 is then removed, and the portions of the STI layer 2230 and the insulating layer 2252 higher than the pillars 2220 are removed with chemical mechanical polishing (CMP), for example. A source/drain region 2260 is formed in the top portion of each pillar 2220 with a doping method, such as, ion implantation, thereby forming a multi-gate transistor constituted of a buried strap 2210, a pillar 2220, a gate dielectric layer 2236, a surrounding gate 2250 and a source/drain region 2260. Thereafter, a bit line 2270 is formed over the substrate 2200 directly contacting with the source/drain regions 2260 and insulated from the word lines 2240 by the insulating layer 2252.

According to the third embodiment of this invention, the width of the pillar can be made sufficiently small by controlling the position shift “ΔS” of active area definition relative to the deep trenches. It is therefore possible to induce full depletion in the pillar in use of the DRAM device, so as to further improve the current switching capability and to eliminate the junction diode leakage.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1-33. (canceled)

34. A DRAM process, comprising:
forming a deep trench capacitor in a semiconductor substrate;
defining an active area over the substrate to form a semiconductor pillar beside the deep trench capacitor and to form an isolation area;
forming a buried strap coupling with the deep trench capacitor in the substrate;
forming a gate dielectric layer on the pillar;
forming a word line including a multi-gate over the substrate, wherein the multi-gate is at least on three sidewalls of the pillar and is separated from the pillar by the gate dielectric layer;
forming a source/drain region in a top portion of the pillar; and
forming a bit line electrically connecting with the source/drain region,
wherein the pillar, the buried strap, the gate dielectric layer, the multi-gate and the source/drain region together constitute a transistor.

35. The DRAM process of claim 34, wherein the buried strap is formed through out diffusion of dopants from a contact portion of an inner electrode of the deep trench capacitor.

36. The DRAM process of claim 34, wherein a mask layer for defining the active area overlaps with the deep trench capacitor.

37. The DRAM process of claim 34, wherein the multi-gate is formed as a treble gate on three sidewalls of the pillar.

38. The DRAM process of claim 37, wherein forming the gate dielectric layer and the word line including the treble gate comprises:
filling the isolation area with an insulating material;
recessing the insulating material to expose a first, a second, and a third sidewalls of the pillar above a predetermined level, wherein the first sidewall faces the deep trench capacitor and the second and third sidewalls are adjacent to the first sidewall;
forming a gate dielectric layer on the pillar;
forming a conductive layer over the substrate; and
patterning the conductive layer to form a word line including a treble gate, wherein the treble gate is formed on the first to third sidewalls and the top of the pillar.

39. The DRAM process of claim 38, wherein the step of forming the source/drain region in the top portion of the pillar comprises:
performing an ion implantation process using the word line as a mask.

40. The DRAM process of claim 38, wherein the conductive layer composes a doped polysilicon layer and a metal comprising layer on the doped polysilicon layer.

41. The DRAM process of claim 38, further comprising:
forming a capping layer on the conductive layer before the conductive layer is patterned, while the capping layer and the conductive layer are patterned successively to form a stacked word line structure; and
forming a spacer on sidewalls of the stacked word line structure.

42. The DRAM process of claim 41, further comprising a step of forming a self-aligned contact (SAC) on the source/drain region before the bit line is formed for electrically connecting the source/drain region and the bit line.

43. The DRAM process of claim 37, wherein forming the gate dielectric layer and the word line including the treble gate comprises:
filling the isolation area with an insulating material;
patterning the insulating material to form a trench in which the word line will be formed, the trench exposing a first sidewall of the pillar above a predetermined level and a portion of a second sidewall and a portion of a third sidewall of the pillar above the predetermined level, wherein the first sidewall faces the deep trench capacitor and the second and third sidewalls are adjacent to the first sidewall;
forming a gate dielectric layer on the pillar; and
forming the word line in the trench.

44. The DRAM process of claim 43, wherein a top surface of the word line is lower than a top surface of the pillar.

45. The DRAM process of claim 44, wherein the step of forming the bit line comprises:
forming an insulating layer in the trench covering the word line; and
forming a patterned conductive layer as a bit line directly contacting with the source/drain region.

46. The DRAM process of claim 34, wherein the multi-gate is formed as a surrounding gate that surrounds sidewalls of the pillar.

47. The DRAM process of claim 46, wherein the width of the pillar is smaller than a feature size.

48. The DRAM process of claim 47, wherein the width of the pillar is sufficiently small for inducing full depletion therein in use of the DRAM cell.

49. The DRAM process of claim 46, wherein forming the gate dielectric layer and the word line including the surrounding gate comprises:
filling the isolation area with an insulating material;
patterning the insulating material to form a trench in which the word line will be formed, the trench exposing all sidewalls of the pillar above a predetermined level;
forming a gate dielectric layer on the pillar; and
forming the word line in the trench.

50. The DRAM process of claim 49, wherein a top surface of the word line is lower than a top surface of the pillar.

51. The DRAM process of claim 50, wherein the step of forming the bit line comprises:
forming an insulating layer in the trench covering the word line; and
forming a patterned conductive layer as a bit line directly contacting with the source/drain region.
